(19) United States
(12) Patent Application Publication
(10) Pub. No.: US 2023/0284463 A1
(43) Pub. Date: Sep. 7, 2023

(54) MEMORY STRUCTURE AND MANUFACTURING METHOD FOR THE SAME

(71) Applicant: MACRONIX INTERNATIONAL CO., LTD., Hsinchu (TW)

(72) Inventors: Erh-Kun LAI, Taichung City (TW); Hsiang-Lan LUNG, Kaohsiung City (TW); Chiao-Wen YEH, New Taipei City (TW)

(21) Appl. No.: 17/686,484

(22) Filed: Mar. 4, 2022

(51) Int. Cl. H01L 27/24; H01L 45/00

(52) U.S. Cl. CPC H01L 27/2481; H01L 27/2427; H01L 45/06; H01L 45/1293; H01L 45/1675

(57) ABSTRACT

A memory structure and a manufacturing method for the same are provided. The memory structure includes a memory element, a spacer structure, and an upper element structure. The memory element includes a lower memory layer and an upper memory layer on the lower memory layer. The spacer structure is on a sidewall surface of the lower memory layer. The upper element structure is electrically connected on the upper memory layer. A recess is defined by a lower surface of the upper element structure, an upper surface of the lower memory layer and a sidewall surface of the upper memory layer.

### BACKGROUND

### Technical Field

The disclosure relates to a memory structure and a manufacturing method for the same.

### Description of the Related Art

There are many applications for switching devices, such as transistors and diodes, in integrated circuits. The emergence of new nonvolatile memory (NVM) technologies-such as phase change memory, resistive memory—has been motivated by exciting applications such as storage class memory, solid-state disks, embedded nonvolatile memory and neuromorphic computing. Many of these applications are suggested to be packed densely in vast “crosspoint” arrays which can offer many gigabytes.

In such arrays, access to any small subset of the array for accurate reading or low-power writing requires a strong nonlinearity in the IV characteristics, so that the currents passing through the selected devices greatly exceed the residual leakage through the nonselected devices. This nonlinearity can either be included explicitly, by adding a discrete access device at each crosspoint, or implicitly with an NVM device which also exhibits a highly nonlinear IV characteristic.

One type of switching device is known as the ovonic threshold switch, based on ovonic materials, characterized by a large drop in resistance at a switching threshold voltage, and recovery of a high resistance, blocking state when the voltage falls below a holding threshold.

Switching devices have been used, for example, in various programmable resistance memory devices comprising high density arrays of cells organized in a crosspoint architecture. Some crosspoint architectures utilize memory cells that include a phase change memory element or other resistive memory element in series with an ovonic threshold switch, for example. Other architectures are utilized, including a variety of 2-dimensional and 3-dimensional array structures, which can also utilize switching devices to select memory elements in the array. Also, ovonic threshold switches have been proposed for a variety of other uses, including so-called neuromorphic computing.

### SUMMARY

The present disclosure relates to a memory structure and a manufacturing method for the same.

According to an embodiment, a memory structure is provided. The memory structure comprises a memory element, a spacer structure, and an upper element structure. The memory element comprises a lower memory layer and an upper memory layer on the lower memory layer. The spacer structure is on a sidewall surface of the lower memory layer. The upper element structure is electrically connected on the upper memory layer. A recess is defined by a lower surface of the upper element structure, an upper surface of the lower memory layer and a sidewall surface of the upper memory layer.

According to another embodiment, a memory structure is provided. The memory structure comprises an upper element structure, a lower element structure, a memory element and a spacer structure. The memory element is electrically connected between the upper element structure and the lower element structure. The memory element comprises a lower memory sidewall surface and an upper memory sidewall surface on an identical side of the memory element. The spacer structure is adjoined with the lower memory sidewall surface. The spacer structure is separated from the upper memory sidewall surface.

According to yet another embodiment, a manufacturing method for a memory structure is provided. The manufacturing method comprises the following steps. A memory device is formed. The memory device comprises a memory element. A spacer structure is formed. The spacer structure covers a lower memory sidewall surface of the memory element and exposes an upper memory sidewall surface of the memory element. An etching step is performed to remove a portion of the memory element from the upper memory sidewall surface exposed by the spacer structure.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a cross-section view of a memory structure in an embodiment.

FIG. 2 illustrates a cross-section view of a memory structure in another embodiment.

FIG. 3 illustrates a cross-section view of a memory structure in yet another embodiment.

FIG. 4 illustrates a three-dimensional view of a memory structure in an embodiment.

FIG. 5 to FIG. 9 illustrate manufacturing methods for a memory structure according to embodiments.

### DETAILED DESCRIPTION

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

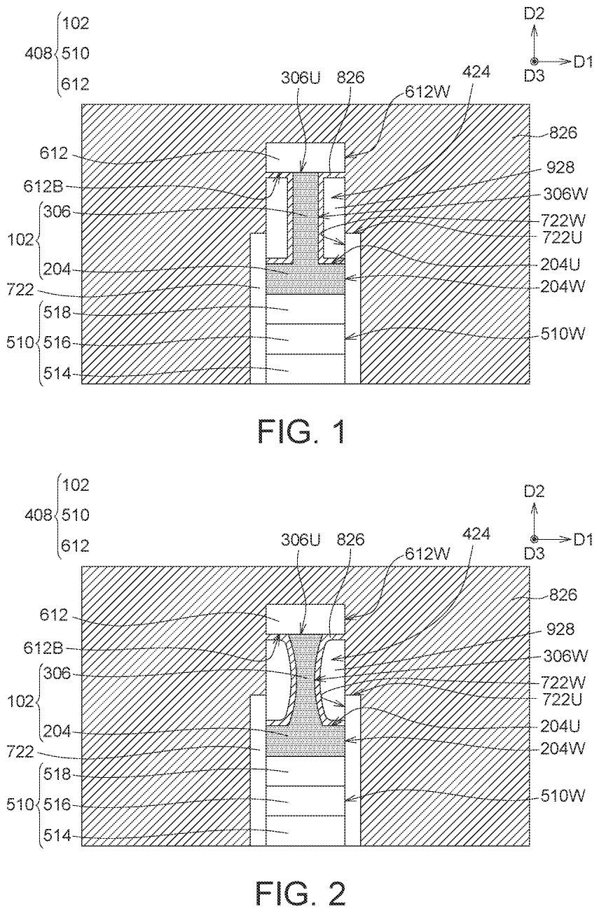

FIG. 1 is referred to, which illustrates a cross-section view of a memory structure in an embodiment. The memory structure shown in FIG. 1 has one memory cell. A memory element 102 comprises a lower memory layer 204 and an upper memory layer 306. The upper memory layer 306 is adjoined on the lower memory layer 204. The lower memory layer 204 comprises a sidewall surface 204W and an upper surface 204U. The sidewall surface 204W of the lower memory layer 204 may be referred to as a lower memory sidewall surface of the memory element 102, which may be a vertical surface. The upper surface 204U of the lower memory layer 204 may be referred to as a lateral memory surface the memory element 102. The upper memory layer 306 comprises a sidewall surface 306W. The sidewall surface 306W of the upper memory layer 306 may be referred to as an upper memory sidewall surface of the memory element 102. In this embodiment, the sidewall surface 306W of the upper memory layer 306 is a straight surface extending along a vertical direction D2. The upper surface 204U of the lower memory layer 204 is between the sidewall surface 204W of the lower memory layer 204 and the sidewall surface 306W of the upper memory layer 306.

A size of the upper memory layer 306 is smaller than a size of the lower memory layer 204 in the same lateral direction. For example, a size of the upper memory layer 306 in a lateral direction D1 is smaller than a size of the lower memory layer 204 in the lateral direction D1. Otherwise, a size of the upper memory layer 306 in a lateral direction D3 is smaller than a size of the lower memory layer 204 in the lateral direction D3. In embodiments, the size of the upper memory layer 306 in the lateral direction (e.g. the lateral direction D1 and/or the lateral direction D3) may be smaller than a critical dimension of a lithography etching process, and therefore the upper memory layer 306 can have a smaller lateral area (contact area) and a smaller volume. As such, a memory device 408 can have a lower reset current.

The memory device 408 comprises a lower element structure 510, the memory element 102 and an upper element structure 612 stacked in the vertical direction D2. The memory element 102 is electrically connected between the lower element structure 510 and the upper element structure 612. The lower memory layer 204 is on an upper surface of the lower element structure 510. The upper element structure 612 is on an upper surface 306U of the upper memory layer 306.

The sidewall surface 204W of the lower memory layer 204, a sidewall surface 510W of the lower element structure 510 and a sidewall surface 612W of the upper element structure 612 may be aligned with each other. The sidewall surface 204W of the lower memory layer 204 and the sidewall surface 510W of the lower element structure 510 may be coplanar.

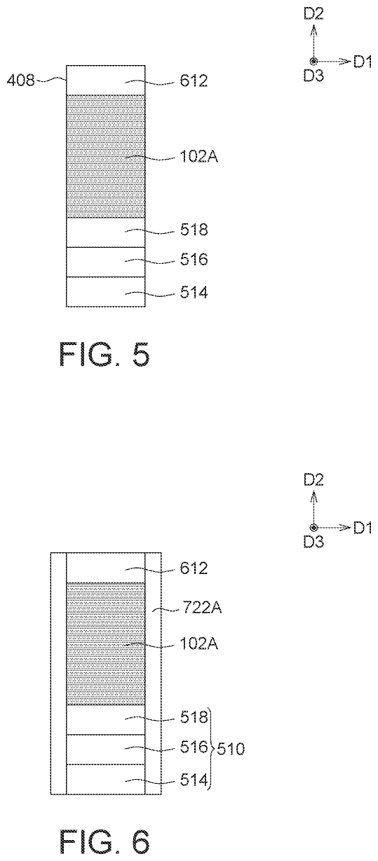

The lower element structure 510 comprises a lower electrode layer 514. The lower element structure 510 may further comprise a switch element 516 and a conductive layer 518. The switch element 516 may be electrically connected between the lower electrode layer 514 and the conductive layer 518. The conductive layer 518 may be electrically connected between the switch element 516 and the lower memory layer 204. The lower element structure 510 of the memory device 408 may further comprise a barrier layer (e.g. a barrier layer 534 shown in FIG. 4) electrically connected between the conductive layer 518 and the lower memory layer 204 of the memory element 102.

The lower electrode layer 514 may be referred to as a bottom electrode. The lower electrode layer 514 may be consisting of a conductive material, and having a thickness of about 3 nm to about 30 nm, preferably about 10 nm. The conductive material comprises a metal such as tungsten (W), or a metal nitride such as TiN, TaN, WN, MoN, TiSiN, TiAIN. For example, the conductive material comprises TiC, SiC, WC, a crystalline carbon such as graphite, Ti, Mo, Ta, TiSi, PtSi, TaSi, and TiW. A carbon-based material may comprise a substantial pure carbon, or a carbon doped with silicon or other materials.

The conductive layer 518 may be consisting of a conductive material, and having a thickness of about 3 nm to about 30 nm, preferably about 10 nm. The conductive material comprises a metal such as tungsten (W), or a metal nitride such as TiN, TaN, WN, MoN, TiSiN, TiAIN. For example, the conductive material comprises TiC, SiC, WC, a crystalline carbon such as graphite, Ti, Mo, Ta, TiSi, PtSi, TaSi, and TiW. A carbon-based material may comprise a substantial pure carbon, or a carbon doped with silicon or other materials. The conductive layer 518 may comprise a barrier layer. The barrier layer may comprise a metal such as tungsten or other metals or metal alloys having a melting point higher than 2000° C. (i.e. refractory metals), or other materials selected for being compatible with the memory element 102. The material of the barrier layer may comprise W, SiC, WC, WN or a combination thereof. The barrier layer may comprise a carbon layer and/or a tungsten layer, such as a carbon/tungsten/carbon stacked layer. In another embodiment, the lower element structure 510 may comprise a tungsten barrier layer electrically connected between the conductive layer 518 and the lower memory layer 204.

The memory element 102 may comprise a chalcogenide material. The chalcogenide material may comprise Ge₁SbₓTe₁ (x=1 to 6), Ge₂Sb₂Te_{y} (y=5 or 6), Ge₂Sb_{z}Te₅ (z=3 or 4), for example. Other illustrative materials comprise gallium (Ga), antimony (Sb) and tellurium (Te) of various stoichiometries. The memory element 102 may comprise an undoped chalcogenide material. The memory element 102 may comprise a doped chalcogenide material, such as a chalcogenide material doped with silicon oxide or silicon nitride. In some embodiments, the memory element 102 may comprise a programmable resistive material such as a metal oxide used for a resistive random access memory, a magnetic material applied in a magnetoresistive random access memory, or a ferroelectric material applied in a ferroelectric random access memory.

The second switch element 516 may be an ovonic threshold switch (OTS) switch layer. The second switch element 516 comprises a chalcogenide material selected for an operation as an ovonic threshold switch (OTS). For example, the OTS material functioned as a switch element may be a compound containing As, Se and Ge, and may be doped with one or more elements selected from the group comprising In, Si, S, B, C, N, and Te. Illustrative OTS switch materials may contain one or more elements selected from the group comprising arsenic (As), tellurium (Te), antimony (Sb), selenium (Se), germanium (Ge), silicon (Si), oxygen (O), and nitrogen (N). Materials for the second switch element 516 may comprise CAsSeGe and the like, for example. In a illustrative example, the second switch element 516 may have a thickness of about 10 nm to about 40 nm, preferably about 30 nm. Czubatyj et al describe applications and electrical properties of thin-film ovonic threshold switches in pages 157-167 of “Thin-Film Ovonic Threshold Switch: Its Operation and Application in Modern Integrated Circuits” in Electronic Materials Letters, Vol. 8, No. 2 (2012).

The upper element structure 612 may be referred to as an upper electrode or a top electrode. The upper element structure 612 may comprise a top electrode layer and/or a barrier layer, but is not limited thereto. The barrier layer may be electrically connected between the top electrode layer and the upper memory layer 306. In embodiments, the memory element 102 is electrically connected between the top electrode layer and the lower electrode layer 514. The upper element structure 612 may be consisting of a conductive material, and having a thickness of about 3 nm to about 30 nm, preferably about 10 nm. The conductive material comprises a metal such as tungsten (W), or a metal nitride such as TiN, TaN, WN, MoN, TiSiN, TiAIN.

For example, the conductive material comprises TiC, SiC, WC, a crystalline carbon such as graphite, Ti, Mo, Ta, TiSi, PtSi, TaSi, and TiW. A carbon-based material may comprise a substantial pure carbon, or a carbon doped with silicon or other materials. The barrier layer may comprise a metal such as tungsten or other metals or metal alloys having a melting point higher than 2000° C. (i.e. refractory metals), or other materials selected for being compatible with the memory element 102. In an embodiment, the conductive layer 518, the lower electrode layer 514 and the upper element structure 612 may have the same material, such as carbon.

A spacer structure 722 is on the sidewall surface 204W of the lower memory layer 204 and the sidewall surface 510W of the lower element structure 510. The spacer structure 722 may be adjoined on the sidewall surface 204W of the lower memory layer 204. The spacer structure 722 is separated from the sidewall surface 306W of the upper memory layer 306 by an insulating element 826 and an air void 928. The sidewall surface 306W of the upper memory layer 306 is spaced apart from the spacer structure 722 by the upper surface 204U of the lower memory layer 204. The upper surface 204U of the lower memory layer 204 may be adjoined between the sidewall surface 306W of the upper memory layer 306 and a sidewall surface 722W of the spacer structure 722. The spacer structure 722 comprises an insulating material, such as a nitride such as silicon nitride, or an oxide such as silicon oxide, but is not limited thereto. In this embodiment, the spacer structure 722 has a uniform thickness (or size in the lateral direction D1). An upper surface 722U of the spacer structure 722 is positioned between the upper surface 204U of the lower memory layer 204 and the upper surface 306U of the upper memory layer 306. In other words, the upper surface 722U of the spacer structure 722 is above the upper surface 204U of the lower memory layer 204, and the upper surface 722U of the spacer structure 722 is below the upper surface 306U of the upper memory layer 306. The position of the upper surface 722U of the spacer structure 722 in the vertical direction D2 is at one-third to one-half of a thickness of the memory element 102 counted from a bottom surface of the memory element 102. For example, as the position of the upper surface 722U of the spacer structure 722 in the vertical direction D2 is at one-third of the thickness of the memory element 102 counted from the bottom surface of the memory element 102, it indicates a distance between the upper surface 722U of the spacer structure 722 and the upper surface 306U of the upper memory layer 306 in the vertical direction D2 is equal to two-thirds of the thickness of the memory element 102. The thickness (or size in the vertical direction D2) of the memory element 102 is a total thickness of the lower memory layer 204 and the upper memory layer 306.

The memory device 408 may have a recess 424 defined by the upper surface 204U of the lower memory layer 204, the sidewall surface 306W of the upper memory layer 306 and a lower surface 612B of the upper element structure 612. The lower surface 612B of the upper element structure 612 may be a lower surface of the top electrode layer, or a lower surface of the barrier layer. The insulating element 826 may be in the recess 424. The insulating element 826 may be on the upper surface 204U of the lower memory layer 204, the sidewall surface 306W of the upper memory layer 306 and the lower surface 612B of the upper element structure 612 in the recess 424. The insulating element 826 may also cover the upper element structure 612 and the spacer structure 722. The air void 928 may be in the insulating element 826 in the recess 424. The air void 928 can provide good thermal isolation effect, and therefore a thermal energy can be concentrated in the memory element 102. As such, the reset current of the memory device 408 can be reduced, and an operating efficiency can be increased. The memory device 408 can be applied for a conductive-bridging random-access memory (CBRAM) or a resistive random-access memory (RRAM).

In embodiments, the spacer structure 722 can support the memory device 408 to prevent the memory device 408 from collapsing. The spacer structure 722 provides the protection effect, and therefore the memory device 408 can be reduced to a small size. For example, the size of the lower memory layer 204 in the lateral direction (e.g. the lateral direction D1 and/or the lateral direction D3) may have a critical dimension. The size of the upper memory layer 306 in the lateral direction (e.g. the lateral direction D1 and/or the lateral direction D3) may be smaller than the critical dimension. As such, the memory device 408 can have a lower reset current.

The sidewall surface 204W and the upper surface 204U of the lower memory layer 204 and the sidewall surface 306W of the upper memory layer 306 may be on at least on identical side of the memory element 102, such as a left side of the memory element 102, and/or a right side of the memory element 102. To facilitate understanding, the left side and the right side of the memory element 102 may be regarded as opposing sides of the memory element 102 in the lateral direction D1. Other possible arrangements and arrangement relations to the other elements can be deduced by analogy.

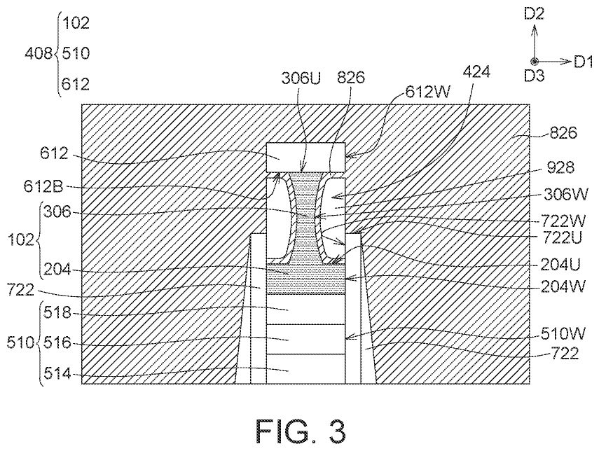

FIG. 2 illustrates a cross-section view of a memory structure in another embodiment, which is different from the memory structure of FIG. 1 in that the sidewall surface 306W of the upper memory layer 306 is a concave curved surface.

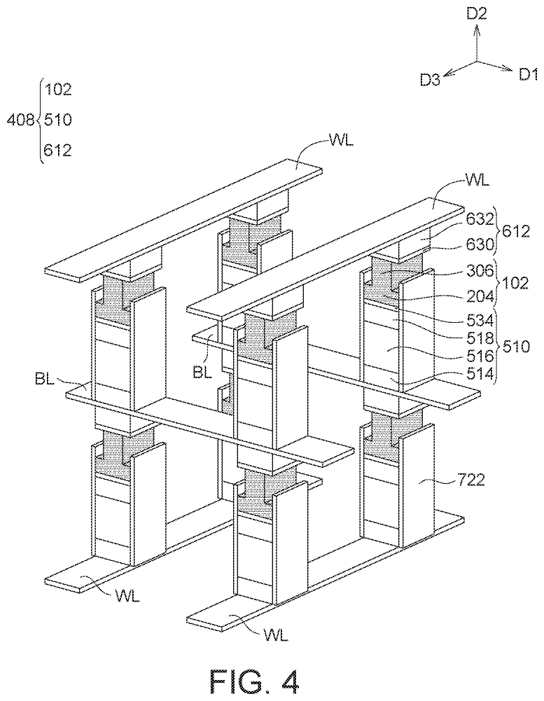

FIG. 3 illustrates a cross-section view of a memory structure in yet another embodiment, which is different from the memory structure of FIG. 2 in that the thickness (or the size in the lateral direction D1) of the spacer structure 722 becomes bigger gradually from top to bottom.

The spacer structure 722 shown in FIG. 3 may be applied for the memory structure shown in FIG. 1.

FIG. 4 illustrates a three-dimensional view of a memory structure in an embodiment. The memory structure shown in FIG. 4 has eight memory cells (memory devices 408) defined between bit lines BL and word lines WL intersected with each other. The upper element structure 612 of the memory cell (memory device 408) comprises a barrier layer 630 and a top electrode layer 632. The barrier layer 630 is electrically connected between the top electrode layer 632 and the upper memory layer 306 of the memory element 102. The top electrode layer 632 is electrically connected between the word line WL and the barrier layer 630. The barrier layer 630 may comprise a metal such as tungsten or other metals or metal alloys having a melting point higher than 2000° C. (i.e. refractory metals), or other materials selected for being compatible with the memory element 102. The lower element structure 510 of the memory device 408 comprises a barrier layer 534 electrically connected between the conductive layer 518 and the lower memory layer 204 of the memory element 102. The memory structure may comprise the insulating element 826 illustrated with referring to FIG. 1.

In an embodiment, the memory device 408 may have a quadrangular pillar shape as shown in FIG. 4. The upper memory layer 306 of the memory element 102 may have the sidewall surfaces 306W diverged from the sidewall surface 204W by the upper surface 204U of the lower memory layer 204 on the opposing sides of the memory element 102 in the lateral direction D1, and having the spacer structures 722 on the sidewall surfaces 306W. However, the present disclosure is not limited thereto. For example, the upper memory layer 306 of the memory element 102 may have the sidewall surfaces 306W diverged from the sidewall surface 204W by the upper surface 204U of the lower memory layer 204 on opposing sides of the memory element 102 in the lateral direction D3, and having the spacer structures 722 on the sidewall surfaces 306W. The lateral direction D1, the vertical direction D2 and the lateral direction D3 may be perpendicular to each other substantially. In another embodiment, the upper memory layer 306 may have only one side having the sidewall surface 306W diverged from the sidewall surface 204W by the upper surface 204U of the lower memory layer 204, and have the sidewall surfaces of the other three sides aligning with the sidewall surfaces of the lower element structure 510. In yet another embodiment, the upper memory layer 306 may have three or four sides having the sidewall surfaces 306W diverged from the sidewall surface 204W by the upper surface 204U of the lower memory layer 204. The memory device 408 may have other pattern shapes, such as a circular pillar shape, a strip shape, etc. Other possible arrangements and arrangement relations to the other elements can be deduced by analogy.

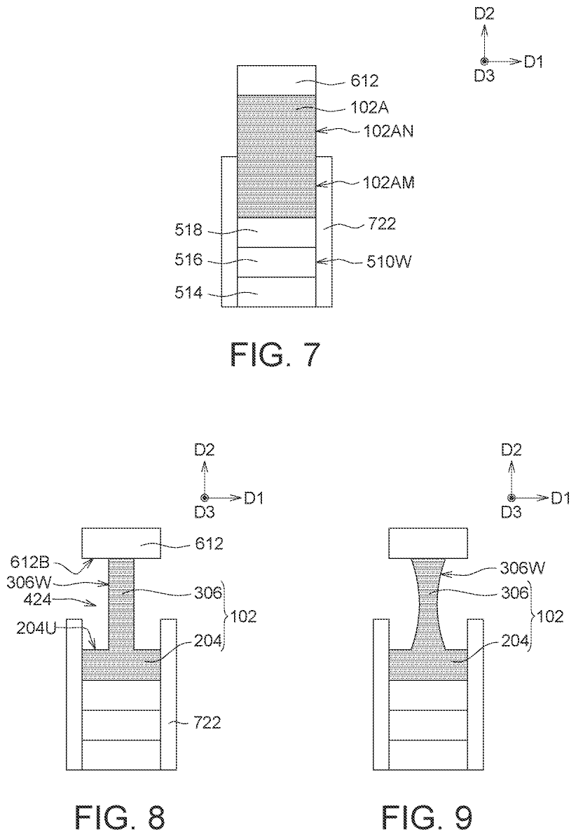

FIG. 5 to FIG. 8 illustrate a manufacturing method for the memory structure of FIG. 1.

Referring to FIG. 5, the memory device 408 may be formed. For example, the lower electrode layer 514, the switch element 516, the conductive layer 518, a memory element 102A and the upper element structure 612 may be stacked in the vertical direction D2 to form a stacked structure, and then a lithography etching process may be used to pattern the stacked structure so as to form the memory device 408. The lower electrode layer 514, the switch element 516, the conductive layer 518, the memory element 102A and the upper element structure 612 of the memory device 408 may have sidewall surfaces aligned with each other. The memory device 408 may have a pillar shape. In embodiments, the memory device 408 may have a critical dimension for the lithography process.

Referring to FIG. 6, a spacer structure 722A may be formed on the sidewall surfaces of the memory element 102A, the lower element structure 510 and the upper element structure 612. An upper portion of the spacer structure 722A may be removed by an etching step so as to form the spacer structure 722 as shown in FIG. 7. This etching step may comprise a reactive-ion etching (RIE) method, but is not limited thereto. In embodiments, the spacer structure 722 can support the memory device 408 to prevent the memory device 408 from collapsing. In embodiments, the spacer structure 722 provides the protection effect, and therefore the memory device 408 can be reduced to a small size such as a critical dimension (CD).

Referring to FIG. 7, the spacer structure 722 covers a lower memory sidewall surface 102AM of the memory element 102A and the sidewall surface 510W of the lower element structure 510. Moreover, the spacer structure 722 exposes an upper memory sidewall surface 102AN of the memory element 102A, and exposes the upper element structure 612. An etching step is performed to remove an upper portion of the memory element 102A from the memory sidewall surface 102AN exposed by the spacer structure 722, and to shrink a size of the upper portion of the memory element 102A in the lateral direction so as to form the memory element 102 as shown in FIG. 8. As such, the remained portion from the etching step for the upper portion of the memory element 102A forms the upper memory layer 306 of the memory element 102. The upper memory layer 306 may have a size smaller than the critical dimension for the lithography process. The etching step may comprise a selective etching method having an etching rate for the memory element 102A faster than an etching rate for the upper element structure 612, and faster than an etching rate for the spacer structure 722. The upper element structure 612 and the spacer structure 722 may be functioned as an etch mask for the etching step. The etching step may comprise an isotropic etching method, such as a reactive-ion etching method. The recess 424 as shown in FIG. 8 is formed through the etching step. The recess 424 is defined by the lower surface 612B of the upper element structure 612, the upper surface 204U of the lower memory layer 204 and the sidewall surface 306W of the upper memory layer 306. The sidewall surface of the spacer structure 722 may be exposed by the recess 424.

Referring to FIG. 1, the insulating element 826 is formed to cover on the memory device 408. The insulating element 826 is in the recess 424. The spacer structure 722 may be covered by the insulating element 826. The step of forming the insulating element 826 may result in the air void 928 in the recess 424.

A profile of the sidewall surface 306W of the upper memory layer 306 may be adjusted according to etch methods and/or etching parameters. In an embodiment, the etching step for the memory element 102A illustrated with referring to FIG. 7 may result in the memory element 102 as shown in FIG. 9 having the sidewall surface 306W of the upper memory layer 306 being a concave curved surface.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A memory structure, comprising:
a memory element comprising a lower memory layer and an upper memory layer on the lower memory layer;
a spacer structure on a sidewall surface of the lower memory layer; and
an upper element structure electrically connected on the upper memory layer, wherein a recess is defined by a lower surface of the upper element structure, an upper surface of the lower memory layer and a sidewall surface of the upper memory layer.

2. The memory structure according to claim 1, further comprising a lower element structure, wherein the memory element is electrically connected between the lower element structure and the upper element structure.

3. The memory structure according to claim 2, wherein the sidewall surface of the lower element structure is aligned with a sidewall surface of the lower memory layer.

4. The memory structure according to claim 1, further comprising an insulating element and/or an air void in the recess.

5. The memory structure according to claim 1, wherein a size of the upper memory layer in a lateral direction is smaller than a size of the lower memory layer in the lateral direction.

6. The memory structure according to claim 1, wherein the spacer structure and the upper memory layer are spaced apart from each other by the upper surface of the lower memory layer.

7. The memory structure according to claim 1, wherein a position of an upper surface of the spacer structure in a vertical direction is at one-third to one-half of a thickness of the memory element counted from a bottom surface of the memory element.

8. A memory structure, comprising:
an upper element structure;
a lower element structure;
a memory element electrically connected between the upper element structure and the lower element structure, wherein the memory element comprises a lower memory sidewall surface and an upper memory sidewall surface on an identical side of the memory element; and
a spacer structure adjoined with the lower memory sidewall surface and separated from the upper memory sidewall surface.

9. The memory structure according to claim 8, further comprising an insulating element and/or an air void on the upper memory sidewall surface of the memory element.

10. The memory structure according to claim 8, wherein the memory element further comprises a lateral memory surface adjoined between the lower memory sidewall surface and the upper memory sidewall surface.

11. The memory structure according to claim 8, wherein a sidewall surface of the lower element structure is aligned with the lower memory sidewall surface of the memory element, the lower element structure comprises a lower electrode layer and a switch element electrically connected between the lower electrode layer and the memory element.

12. The memory structure according to claim 8, wherein the memory element comprises a phase change memory material.

13. The memory structure according to claim 8, wherein the upper element structure comprises a top electrode layer, the lower element structure comprises a lower electrode layer, the memory element is electrically connected between the top electrode layer and the lower electrode layer.

14. The memory structure according to claim 13, wherein the lower element structure further comprises a switch element electrically connected between the lower electrode layer and the memory element.

15. The memory structure according to claim 8, wherein a position of an upper surface of the spacer structure in a vertical direction is at one-third to one-half of a thickness of the memory element counted from a bottom surface of the memory element.

16. A manufacturing method for a memory structure, comprising:
forming a memory device, wherein the memory device comprises a memory element;
forming a spacer structure, wherein the spacer structure covers a lower memory sidewall surface of the memory element and exposes an upper memory sidewall surface of the memory element; and
performing an etching step to remove a portion of the memory element from the upper memory sidewall surface exposed by the spacer structure.

17. The manufacturing method for the memory structure according to claim 16, wherein a recess is formed through the etching step, the recess is defined by a sidewall surface of an upper memory layer and an upper surface of a lower memory layer of the memory element.

18. The manufacturing method for the memory structure according to claim 17, further comprising forming an insulating element in the recess and covering on the memory device after the etching step.

19. The manufacturing method for the memory structure according to claim 18, wherein an air void is generated in the recess through the forming the insulating element.

20. The manufacturing method for the memory structure according to claim 16, wherein the memory device further comprises an upper element structure and a lower element structure, the memory element is electrically connected between the upper element structure and the lower element structure, the spacer structure covers the lower element structure, the spacer structure exposes the upper element structure.
